(19) United States
(12) Patent Application Publication
(10) Pub. No.: US 2024/0065508 A1
(43) Pub. Date: Feb. 29, 2024

(54) WATER SHORTAGE DETECTION AND WATER SUPPLY SYSTEM FOR ROBOT CLEANER

(71) Applicant: EVERYBOT INC., Seongnam-si, Gyeonggi-do (KR)

(72) Inventors: Woo Chul JUNG, Seongnam-si, Gyeonggi-do (KR); Bong Yun KIM, Seongnam-si, Gyeonggi-do (KR)

(21) Appl. No.: 18/268,117

(22) PCT Filed: Oct. 14, 2021
(86) PCT No.: PCT/KR2021/014201

§ 371 Date: Jun. 16, 2023

(30) Foreign Application Priority Data
Dec. 29, 2020 (KR) 10-2020-0186543

(51) Int. Cl. A47L 11/40; G01R 19/165

(52) U.S. Cl. CPC A47L 11/4011; A47L 11/4066; A47L 11/4088; G01R 19/165

(57) ABSTRACT

A water shortage detection system comprises: a body; a drive unit which is provided in the body to supply power for traveling of a robot cleaner; a plurality of rotary members which rotate about a plurality of respective rotation axes by the power from the drive unit and to which cleaners for wet cleaning of a surface to be cleaned can be fixed respectively; a water tank which is provided in the body to store water; a pump motor which supplies water stored in the water tank to the rotary members; and a control unit which measures the load current of the pump motor, wherein a water shortage state in the water tank is detected on the basis of the measured value of the load current of the pump motor.

### TECHNICAL FIELD

The present invention relates to a water shortage detection and water supply system for a robot cleaner.

### BACKGROUND ART

In accordance with the development of an industrial technology, various devices are being automated. As is well known, a robot cleaner is used as a device that automatically cleans an area to be cleaned by inhaling foreign matters such as dust from a surface to be cleaned or wiping foreign matters from the surface to be cleaned while traveling in an area to be cleaned without user manipulation.

In general, such a robot cleaner may include a vacuum cleaner that performs cleaning using a suction force generated from a motor.

The robot cleaner including such a vacuum cleaner have limitations in not being able to remove foreign matters, stains, etc., adhered to the surface to be cleaned. Recently, a robot cleaner capable of performing wet cleaning with a mop attached to the robot cleaner is emerging.

A technology for supplying water (moisture) to a mop from a water tank combined with a robot cleaner has been developed, but since a user has to manually supply water to the water tank, technologies for notifying the robot cleaner of water shortage in the water tank have been developed.

However, in general, the technology of notifying water shortage in the water tank is made through a sensor coupled to the water tank, but there was a problem in that the manufacturing cost increases due to the sensor, and many A/S cases occurred due to frequent breakdowns.

In addition, a technology of controlling a water supply amount by adjusting the amount of water supplied to the mop to perform cleaning suitable for the surface to be cleaned or the surrounding environment has been developed, which is made through a sensor that detects the amount of moisture in the surface to be cleaned, so there is a problem in that the manufacturing costs increase and many A/S cases occur due to frequent breakdowns.

### DISCLOSURE

### Technical Problem

The present invention is devised from the above needs, and an object of the present invention is to detect water shortage in a water tank or control water supply without a separate sensor to reduce manufacturing cost and reduce battery consumption to secure efficient wet cleaning and cleaning time per unit time through a process of measuring load currents of a pump motor and a driving motor by a pump motor load current detection unit and a driving motor load current detection unit of a control unit and comparing a measured value with a reference value.

### Technical Solution

According to an embodiment of the present invention, a water shortage detection system includes: a body; a drive unit which is provided in the body to supply power for traveling of a robot cleaner; a plurality of rotary members which rotate about a plurality of respective rotation axes by the power from the drive unit and to which cleaners for wet cleaning of a surface to be cleaned can be fixed respectively; a water tank which is provided in the body to store water; a pump motor which supplies water stored in the water tank to the rotary members; and a control unit which measures the load current of the pump motor, in which a water shortage state in the water tank may be detected on the basis of the measured value of the load current of the pump motor.

A water shortage state in the water tank may be detected by comparing a preset reference value of the load current of the pump motor and the measured value of the load current of the pump motor.

When the measured value of the load current of the pump motor is less than or equal to the reference value of the load current of the pump motor, the water shortage state may be notified to the user.

The water shortage state in the water tank may be detected based on a variation change of the measured value of the load current of the pump motor.

When a section where the variation change of the measured value of the load current of the pump motor is constant is repeated, the water shortage state may be notified to a user.

The robot cleaner may travel by using a frictional force between the surface to be cleaned and the fixed cleaner, which is generated as the cleaner rotates, as a moving power source.

The plurality of rotary members may include a first rotary member, a second rotary member, and a third rotary member.

A water supply system for a robot cleaner includes: a body; a drive unit which is provided in the body to supply power for traveling of a robot cleaner; a plurality of rotary members which rotate about a plurality of respective rotation axes by the power from the drive unit and to which cleaners for wet cleaning of a surface to be cleaned is be fixed respectively; a driving motor which provides the power to the plurality of rotary members; a water tank which is provided in the body to store water; a pump motor which supplies water stored in the water tank to the rotary members; and a control unit which measures a load current of the driving motor, in which a water supply amount of the water tank is controlled based on a measured value of the load current of the driving motor.

The water supply amount of the water tank may be detected by comparing a preset reference value of the load current of the driving motor and the measured value of the load current of the driving motor.

When the measured value of the load current of the driving motor is greater than or equal to the reference value of the load current of the driving motor, the water supply amount may be controlled to be reduced.

The reference value of the load current of the driving motor may be the reference value of the load current of the driving motor in a linear traveling or rotational traveling state of the robot cleaner.

The robot cleaner may travel by using a frictional force between the surface to be cleaned and the fixed cleaner, which is generated as the cleaner rotates, as the moving power source.

The plurality of rotary members may include a first rotary member, a second rotary member, and a third rotary member.

### Advantageous Effects

According to the present invention, it is possible to reduce manufacturing costs by detecting water shortage in a water tank or controlling a water supply amount through a process of measuring load currents of a pump motor and a driving motor by a pump motor load current detection unit and a driving motor load current detection unit of a control unit and comparing a measured value with a reference value.

In addition, it is possible to avoid a traveling obstacle section by determining a condition of a surface to be cleaned in advance, and secure efficient wet cleaning and cleaning time per unit time by reducing battery consumption.

### BRIEF DESCRIPTION OF THE DRAWINGS

FIGS. 1 and 2 are a perspective view and a front view illustrating an appearance of a robot cleaner according to an embodiment of the present invention.

FIG. 3 is a block diagram illustrating the robot cleaner according to the embodiment of the present invention.

FIG. 4 is a diagram illustrating a traveling operation of a robot cleaner according to an embodiment of the present invention.

FIGS. 5 and 6 are diagrams illustrating a configuration of a drive unit according to an embodiment of the present invention.

FIG. 7 is a block diagram illustrating a configuration for supplying water to a cleaner of a robot cleaner according to an embodiment of the present invention.

FIG. 8 is a diagram illustrating a case in which a measured value of a load current of a pump motor is recognized as an error in the robot cleaner according to the embodiment of the present invention or another embodiment of the present invention.

FIG. 9 is a flowchart illustrating a water shortage detection process of a robot cleaner according to an embodiment of the present invention.

FIG. 10 is a flowchart illustrating a water shortage detection process of a robot cleaner according to another embodiment of the present invention.

FIG. 11 is a flowchart illustrating a process of controlling a water supply amount of a robot cleaner according to an embodiment of the present invention.

FIG. 12 is a flowchart illustrating a process of controlling a water supply amount of a robot cleaner according to another embodiment of the present invention.

FIG. 13 is a diagram illustrating a robot cleaner with two rotary members.

### BEST MODE

The following description illustrates only a principle of the present invention.

Therefore, those skilled in the art may implement the principle of the present invention and invent various apparatuses included in the spirit and scope of the present invention although not clearly described or illustrated in the present specification. In addition, it is to be understood that all conditional terms and exemplary embodiments mentioned in the present specification are obviously intended only to allow those skilled in the art to understand a concept of the present invention in principle, and the present invention is not limited to exemplary embodiments and states particularly mentioned as such.

Further, it is to be understood that all detailed descriptions mentioning specific exemplary embodiments of the present invention as well as principles, aspects, and exemplary embodiments of the present invention are intended to include structural and functional equivalences thereof. Further, it is to be understood that these equivalences include an equivalence that will be developed in the future as well as an equivalence that is currently well-known, that is, all elements invented so as to perform the same function regardless of a structure.

Therefore, it is to be understood that, for example, block diagrams of the present specification illustrate a conceptual aspect of an illustrative circuit for embodying a principle of the present invention. Similarly, it is to be understood that all flow charts, state transition diagrams, pseudo-codes, and the like, illustrate various processes that may be tangibly embodied in a computer readable medium and that are executed by computers or processors regardless of whether or not the computers or the processors are clearly illustrated.

Functions of various elements including processors or functional blocks represented as concepts similar to the processors and illustrated in the accompanying drawings may be provided using hardware having capability to execute software in connection with appropriate software as well as dedicated hardware. When the functions are provided by the processors, they may be provided by a single dedicated processor, a single shared processor, or a plurality of individual processors, and some of them may be shared with each other.

In addition, the explicit use of terms presented as a processor, control, or similar concepts should not be construed as exclusively citing hardware with ability capable of executing software, but it should be understood that it implicitly includes, without limitation, digital signal processor (DSP) hardware, a ROM, a RAM, and a non-volatile memory for storing software. The above-mentioned terms may also include well-known other hardware.

In the claims of the present specification, components represented as means for performing functions mentioned in a detailed description are intended to include all methods for performing functions including all types of software including, for example, a combination of circuit devices performing these functions, firmware/micro codes, etc., and are coupled to appropriate circuits for executing the software so as to execute these functions. It is to be understood that since functions provided by variously mentioned means are combined with each other and are combined with a method demanded by the claims in the present invention defined by the claims, any means capable of providing these functions are equivalent to means recognized from the present specification.

The above-mentioned objects, features, and advantages will become more obvious from the following detailed description associated with the accompanying drawings. Therefore, those skilled in the art to which the present invention pertains may easily practice a technical idea of the present invention. Further, in describing the present disclosure, in the case in which it is decided that a detailed description of a well-known technology associated with the present disclosure may unnecessarily make the gist of the present disclosure unclear, it will be omitted.

Hereinafter, various exemplary embodiments of the present invention will be described in detail with reference to the accompanying drawings.

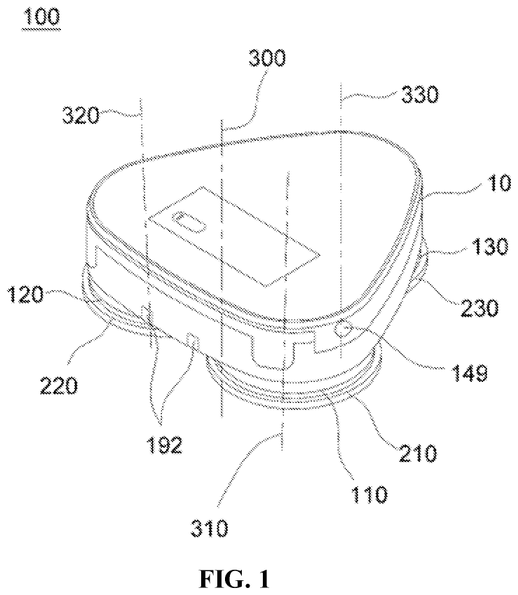

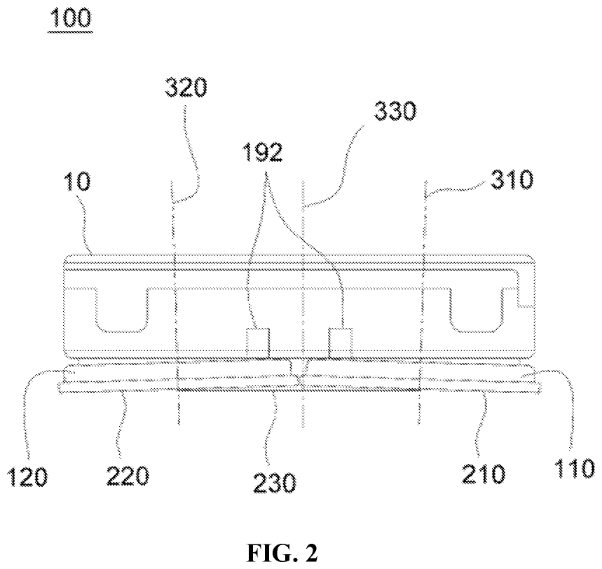

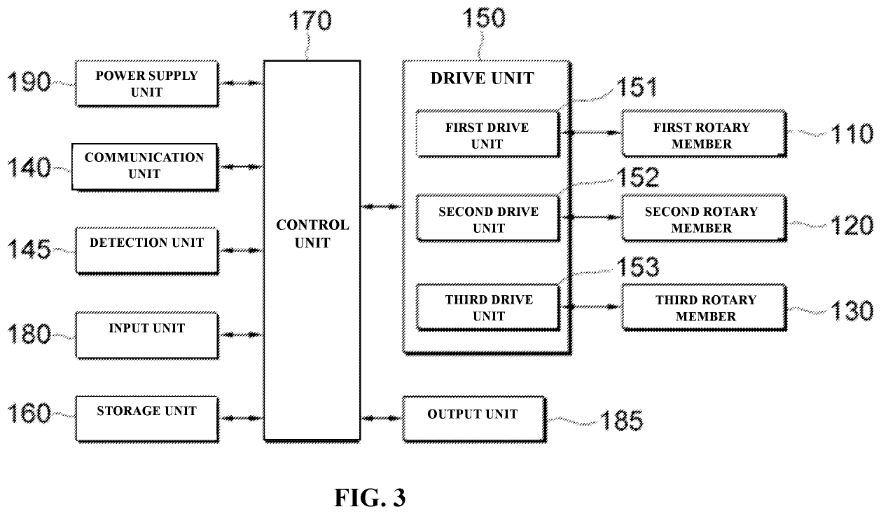

FIGS. 1 and 2 are a perspective view and a front view illustrating an appearance of a robot cleaner according to an embodiment of the present invention, and FIG. 3 is a block diagram illustrating the robot cleaner according to the embodiment of the present invention.

As illustrated in FIGS. 1 to 3, a robot cleaner 100 according to an embodiment of the present invention may be configured to include a body 10, a drive unit 150, a first rotary member 110, and a second rotary member 120, a third rotary member 130, and a control unit 170.

In addition, referring to FIG. 3, the robot cleaner 100 according to the embodiment of the present invention may be configured to further include at least one of a detection unit 145, a communication unit 140, a storage unit 160, an input unit 180, an output unit 185, and a power supply unit 190.

The body 10 may be structurally configured to form an appearance of the robot cleaner 100.

According to an embodiment of the present invention, a bumper (not illustrated) for protecting the body 10 from external shocks may be formed around an outer circumference of the body 10.

The drive unit 150 may be provided on the body 10 to supply power for traveling the robot cleaner 100.

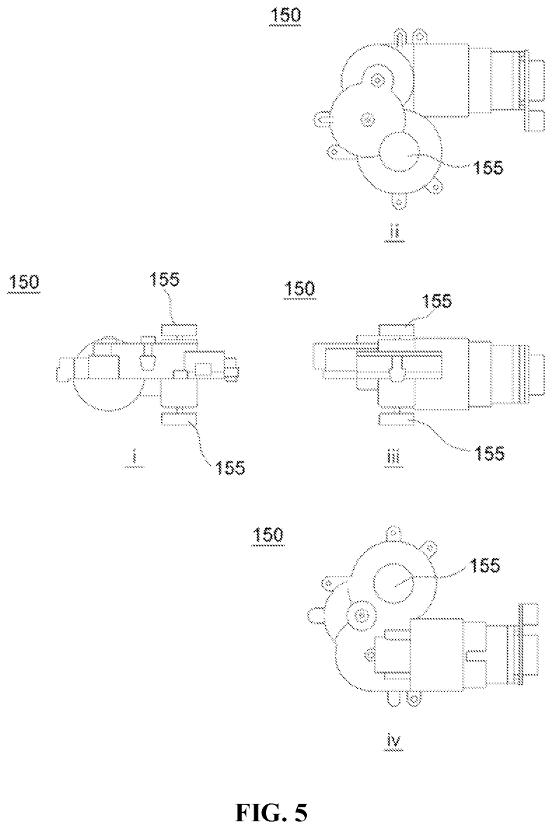

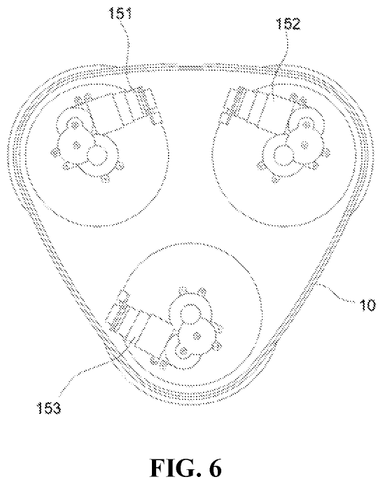

Each of the first rotary member 110, the second rotary member 120, and the third rotary member 130 may each rotate about a first rotation axis 310, a second rotation axis 320, and a third rotation axis 330 by the power from the drive unit 150. Here, the rotation in a clockwise direction (CW) or counterclockwise direction (CCW) may be selected based on the rotation axis. The drive unit 150 may be a component for driving the first rotary member 110, the second rotary member 120, and the third rotary member 130. More specifically, the drive unit 150 may supply power to rotate the first rotary member 110, the second rotary member 120, and the third rotary member 130 under the control of the control unit 170. Here, as illustrated in FIGS. 5 and 6, the drive unit 150 may include a first drive unit 151, a second drive unit 152, and a third drive unit 153 that drive the first rotary member 110, the second rotary member 120, and the third rotary member 130, respectively.

In this case, in the present invention, a driving motor M2 may be provided in the drive unit. The driving motor M2 is a motor for providing power in the drive unit, and a detailed description thereof will be given below.

A first cleaner 210, a second cleaner 220, and a third cleaner for wet cleaning a surface to be cleaned are fixable to the first rotary member 110, the second rotary member 120, and the third rotary member 130, respectively.

The robot cleaner 100 may travel while performing the wet cleaning using cleaners 210, 220, and 230. Here, the wet cleaning may refer to cleaning that wipes the surface to be cleaned using the cleaners 210, 220, and 230, and may include, for example, cleaning using dry rags, etc., cleaning using liquid-soaked rags, etc.

The first cleaner 210, the second cleaner 220, and the third cleaner 230 may be made of materials, which may wipe various surfaces to be cleaned, such as microfiber cloths, mops, non-woven fabrics, and brushes, to remove foreign matters stuck on a floor surface through rotational motion. In addition, shapes of the first cleaner 210, the second cleaner 220, and the third cleaner 230 may be circular as illustrated in FIGS. 1 and 2, but may be implemented in various shapes without limitation.

The cleaner rotates clockwise (CW) or counterclockwise (CCW) in response to a rotation direction of the rotary member.

In addition, the first, second, and third cleaners 210, 220, and 230 may be fixed by a method of covering the first, second, and third cleaners 210, 220, and 230 on the corresponding rotary members 110, 120, and 130, respectively, or by using a separate attachment means. For example, the first cleaner 210, the second cleaner 220, and the third cleaner 230 may be attached to and fixed to a fixing member by a Velcro tape, etc.

The robot cleaner 100 according to the embodiment of the present invention may be rubbed against the surface to be cleaned as the first cleaner 210, the second cleaner 220, and the third cleaner 230 rotate by the rotational motions of the first rotary member 110, the second rotary member 120, and the third rotary member 130, thereby removing foreign matters, etc., adhered to the floor.

In addition, when a frictional force is generated between the cleaners 210, 220, and 230 and the surface to be cleaned, the frictional force may be used as a moving force source for the robot cleaner 100.

In addition, since the first rotary member 110, the second rotary member 120, and the third rotary member 130 form a predetermined angle with the surface to be cleaned, a frictional force may be generated between the cleaners coupled to each rotary member and the surface to be cleaned, so the robot cleaner 100 may clean the surface to be cleaned while moving.

The detection unit 145 may detect various types of information necessary for the operation of the robot cleaner 100 and transmit a detection signal to the control unit 170. Meanwhile, the communication unit 140 may include one or more modules enabling wireless communication between the robot cleaner 100 and another wireless terminal or between the robot cleaner 100 and a network in which another wireless terminal is positioned. For example, the communication unit 140 may communicate with a wireless terminal, which is a remote control unit. To this end, the communication unit 140 may include a short range communication module, a wireless Internet module, or the like.

An operation state, an operation method, or the like, of the robot cleaner 100 may be controlled by a control signal received by the communication unit 140 as described above. An example of a terminal controlling the robot cleaner 100 may include a smart phone, a tablet personal computer, a personal computer, a remote control unit, and the like, that may communicate with the robot cleaner 100.

Meanwhile, the storage unit 160 may store a program for an operation of the control unit 170 therein, and temporarily store input/out data therein. The storage unit 160 may include at least one of a flash memory type storage medium, a hard disk type storage medium, a multimedia card micro type storage medium, a card type memory (for example, an SD or XD memory, or the like), a random access memory (RAM), a static random access memory (SRAM), a read-only memory (ROM), an electrically erasable programmable read-only memory (EEPROM), a programmable read-only memory (PROM), a magnetic memory, a magnetic disk, and an optical disk.

The input unit 180 may receive a user input for manipulating the robot cleaner 100. In particular, the input unit 180 may receive a user input for selecting an operation mode of the robot cleaner 100.

Here, the input unit 180 may be formed of a keypad, a dome switch, a touch pad (a resistive or capacitive touch pad), a jog wheel, a jog switch, or the like.

The output unit 185 is to generate an output related to a visual sense, an auditory sense, or the like. Although not illustrated, a display unit, a sound output module, an alarm unit, and the like, may be included in the output unit 185.

The display unit may display (output) information processed in the robot cleaner 100. For example, when the robot cleaner is cleaning, a user interface (UI) or a graphic user interface (GUI) displaying a cleaning time, a cleaning method, a cleaning area, etc., related to a cleaning mode may be displayed.

The power supply unit 190 supplies power to the robot cleaner 100. Specifically, the power supply unit 190 supplies power to each functional unit constituting the robot cleaner 100, and when the remaining power is insufficient, it may be charged by receiving a charging current from an external charger. Here, the power supply unit 190 may be implemented by a rechargeable battery.

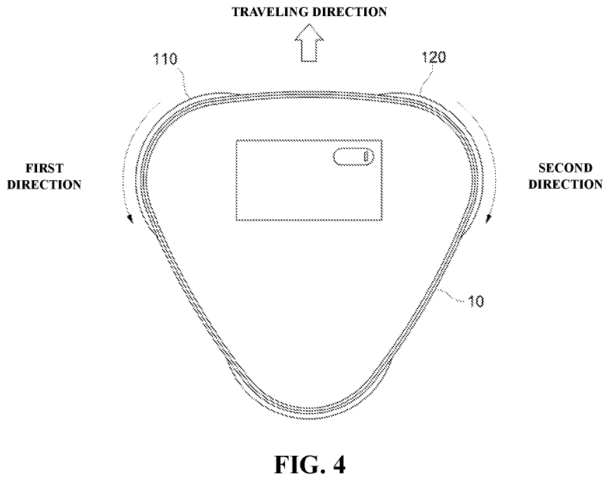

FIG. 4 is a diagram illustrating a traveling operation of the robot cleaner according to the embodiment of the present invention.

As illustrated in FIG. 4, the first rotary member 110 and the second rotary member 120 are disposed in the front, and the third rotary member 130 is disposed in the rear, so the robot cleaner 100 may travel linearly forward. In addition, as another embodiment, the third rotary member 130 is disposed in the front, and the first rotary member 110 and the second rotary member 120 are disposed in the rear, so the robot cleaner 100 may travel linearly forward. In addition, the robot cleaner 100 may travel backwards in an opposite direction to the forward traveling.

In addition, the robot cleaner 100 may travel on a curve along a trajectory including a curve having a predetermined radius of curvature under the control of the control unit 170 while traveling linearly.

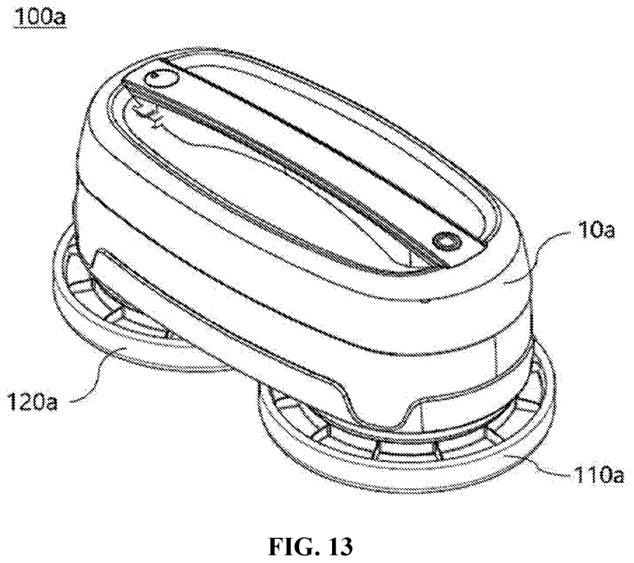

The robot cleaner having the plurality of rotary members may be a robot cleaner 100a having not only three rotary members 110, 120, and 130 as described above, but also two rotary members 110a and 120a as illustrated in FIG. 13

Therefore, the water shortage detection and supply system described below is not limited to the robot cleaner having three rotary members, and may also be applied to the robot cleaner 100a having two rotary members 110a and 120a as illustrated in FIG. 13. However, for convenience of description, the following description is based on the robot cleaner to which three rotary members are applied.

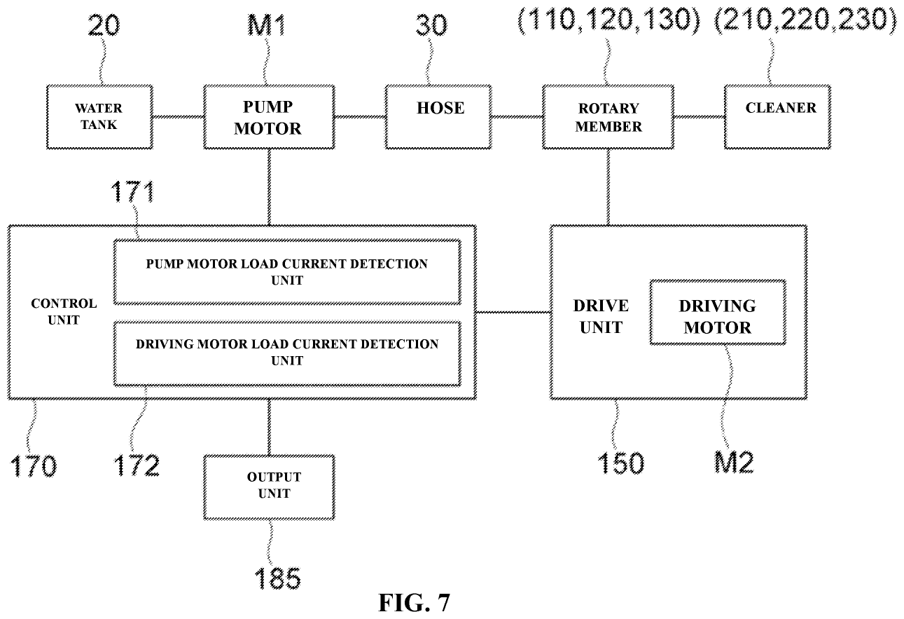

FIG. 7 is a block diagram illustrating a configuration for supplying water to a cleaner of the robot cleaner according to the embodiment of the present invention. Hereinafter, a water shortage detection system of a robot cleaner according to an embodiment of the present invention will be described.

The robot cleaner according to the embodiment of the present invention includes a water tank 20 for storing water inside the body 10. A shape of the water tank 20 is not limited to any one shape.

The water tank 20 is coupled to a pump motor M1. The pump motor M1 serves to supply water stored in the water tank 20 to the rotary members 110, 120, and 130. The pump motor M1 is interlocked with the control unit 170. In addition, the pump motor M1 and the rotary members 110, 120, and 130 are connected through a hose 30.

The control unit 170 may measure a load current of the pump motor M1. In more detail, the control unit 170 includes a pump motor load current detection unit 171 and a driving motor load current detection unit 172. The driving motor load current detection unit 172 will be described in detail later.

If the robot cleaner according to the embodiment of the present invention starts traveling, when the wet cleaning is selected, the pump motor M1 operates to supply water stored in the water tank 20 to the cleaners 210, 220, and 230. In this case, the pump motor load current detection unit 171 measures the load current of the pump motor M1. The load current may be measured through, for example, an average load current (pump motor on calibration).

In the present invention, the control unit 170 may recognize a water shortage detection state by comparing the measured value of the load current of the pump motor M1 with a reference value of the load current of the pump motor. In the present invention, the water shortage detection state is also referred to as “error recognition.”

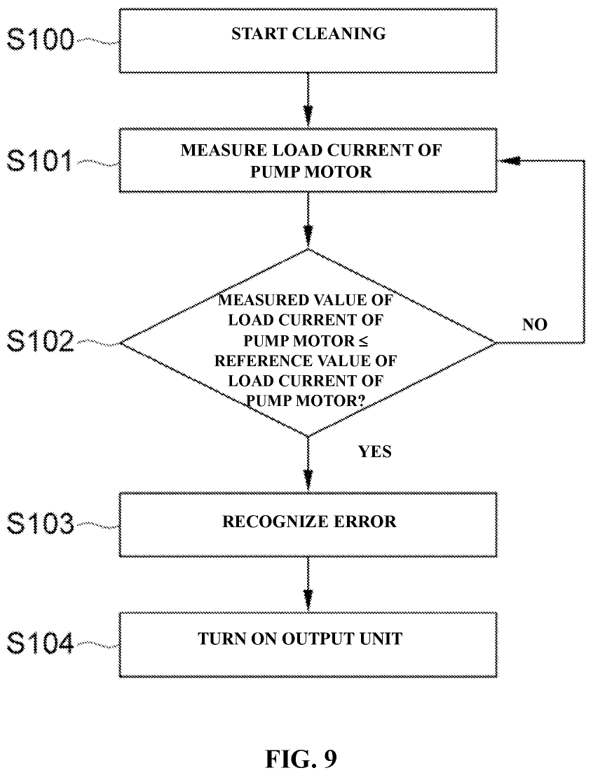

FIG. 9 is a flowchart illustrating a water shortage detection process of a robot cleaner according to an embodiment of the present invention.

First, the robot cleaner starts cleaning (S100). Here, dry cleaning may be performed without the pump motor M1 being driven according to control or a user selection, but hereinafter, it is assumed that wet cleaning is performed with the pump motor M1 being driven. The robot cleaner may travel as described above, and at the same time, water may be supplied to the cleaners 210, 220, and 230 to perform the wet cleaning.

Next, the pump motor load current detection unit 171 measures the load current of the pump motor M1 (S101). The measured value of the load current is referred to as the “measured value of the load current of the pump motor.” In this case, the “reference value of the load current of the pump motor” is preset in the control unit 170. The “reference value of the load current of the pump motor” is a reference value for determining that it is not a normal state when the load current of the pump motor M1 falls below a certain value. The reference value of the load current of the pump motor may be pre-stored in the control unit 170. In addition, a design change or a change by a user may be possible.

When the pump motor M1 operates, the load current is generated in the pump motor M1. The pump motor load current detection unit 171 detects the load current of the pump motor M1. When the water stored in the water tank 20 is insufficient, the amount of water supplied to the hose through the pump motor M1 is reduced, and thus, a load current value of the pump motor M1 is reduced. In the present invention, the water shortage state of the water tank 20 is detected by comparing the load current value of the pump motor M1.

The control unit 170 compares the measured value of the load current of the pump motor measured by the pump motor load current detection unit 171 with a preset reference value of the load current of the pump motor (S102).

In this case, when the measured value of the load current of the pump motor is less than or equal to the reference value of the load current of the pump motor, the control unit 170 detects a water shortage state and recognizes the detected water shortage state as an error (S103). In the opposite case, the control unit 170 determines that the amount of water is normal and continuously compares the measured value of the load current of the pump motor with the reference value of the load current through feedback.

When the control unit 170 recognizes the water shortage state as the error, the user may notify a user of the water shortage state through the output unit 185 (S104). As described above, the output unit 185 is to generate an output related to a visual sense, an auditory sense, or the like. Although not illustrated, a display unit, a sound output module, an alarm unit, and the like, may be included in the output unit 185. The user may recognize the water shortage state and supply water to the water tank 20, and continue to perform wet cleaning.

As described above, in the related art, a sensor was used as a means for detecting the water shortage in the water tank, but in the present invention, the measured value of load current of the pump motor is compared with the reference value of the load current of the pump motor to determine the water shortage in the water tank, which has the advantage of reducing manufacturing costs. In addition, the structure is simplified compared to the existing sensor type, which has the advantage of lowering a failure rate of the robot cleaner.

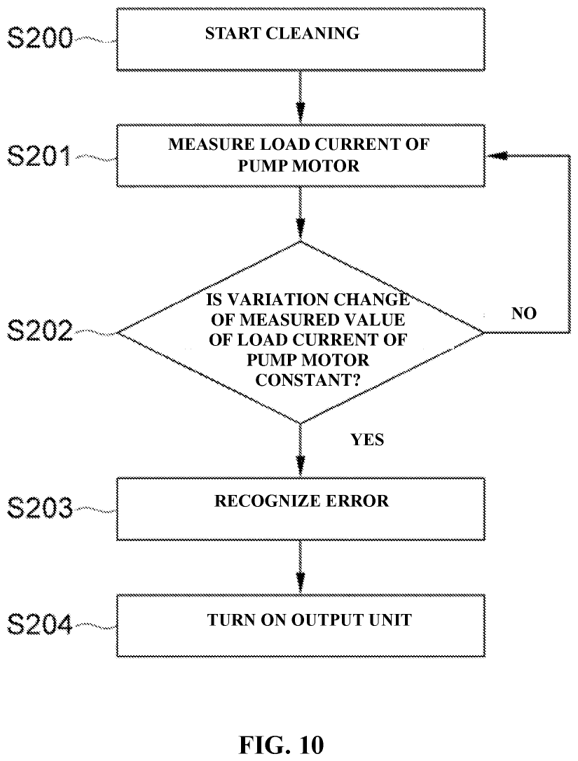

FIG. 10 is a flowchart illustrating a water shortage detection process of a robot cleaner according to another embodiment of the present invention.

A robot cleaner according to another embodiment of the present invention shares a step of starting cleaning and a step of measuring a load current of a pump motor with the robot cleaner according to the embodiment (S200 and S201). In order to avoid duplication of description, the contents thereof will be omitted.

In this case, the robot cleaner according to another embodiment of the present invention does not compare a measured value of a load current of a pump motor with a reference value of a load current of the pump motor, but measures a variation change of the measured value of the load current of the pump motor itself (S202).

When water is sufficiently supplied to the water tank 20, the phenomenon occurs that the measured value of the load current of the pump motor measured by the pump motor M1 continuously bounces. As a result, the variation change of the measured value of the load current of the pump motor is not constant. However, when water is insufficient in the water tank 20, the bouncing phenomenon of the measured value of the load current of the pump motor may not occur, and the variation change of the measured value of the load current of the pump motor becomes constant.

Therefore, when the variation width of the measured value of the load current of the pump motor becomes constant in the robot cleaner, the control unit 170 detects a water shortage state and recognizes the detected water shortage state as an error (S203). In the opposite case, the control unit 170 determines that the amount of water is normal and continuously determines whether the measured value of the load current of the pump motor is constant through feedback.

When the control unit 170 recognizes the water shortage state as the error, the control unit 170 may notify a user of the water shortage state through the output unit 185 (S204). This shares step S104 according to the embodiment of the present invention. In order to avoid duplication of description, the contents thereof will be omitted. In addition, another embodiment of the present invention has the same effect as the embodiment, and in addition, has the advantage of increasing a calculation speed because it does not go through a process of comparing with the reference value of the load current of the pump motor.

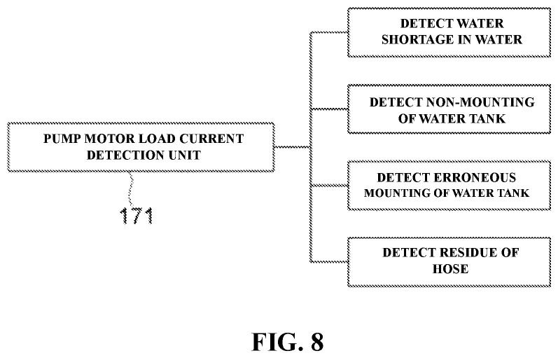

FIG. 8 is a diagram illustrating a case in which the measured value of the load current of the pump motor is recognized as an error in the robot cleaner according to the embodiment of the present invention or another embodiment of the present invention.

First, as described above, the water shortage state in the water tank 20 may be detected. In addition, the case in which the water tank 20 is not mounted on the body 10 is also recognized as an error, so the non-mounted state of the water tank 20 may be detected.

In addition, the case in which the water tank 20 is not correctly mounted on a designated position of the body 10 is also recognized as an error, so the erroneously mounted state of the water tank 20 may be detected.

In addition, the case in which residues remain in the hose 30 connecting the water tank 20 and the pump motor M1 is also recognized as an error, so the residues in the hose 30 may be detected. In this case, the residue removal function may be performed by the control unit 170.

Therefore, by comparing the measured value of the load current of the pump motor and the reference value of the load current of the pump motor measured by the pump motor load current detection unit 171 or determining whether the variation width of the measured value of the load current of the pump motor is constant, it is possible to determine errors in various cases as described above.

Referring to FIG. 7, the drive unit 150 includes a driving motor M2 that provides power to the rotary members 110, 120, and 130. In addition, the control unit 170 includes the driving motor load current detection unit 172 that measures the load current of the driving motor M2. Hereinafter, a water supply system of a robot cleaner according to an embodiment of the present invention will be described.

The control unit 170 may measure a load current of the driving motor M2. When the robot cleaner according to the embodiment of the present invention starts traveling, the driving motor M2 operates to rotate the rotary members 110, 120, and 130 and the cleaners 210, 220, and 230 regardless of the wet cleaning or the dry cleaning. In this case, the driving motor load current detection unit 172 measures the load current of the driving motor M2.

The load current may be measured through, for example, an average load current (wheel motor on calibration), and each load current of the plurality of rotary members 110, 120, and 130 may be measured.

In the present invention, the control unit 170 may control the water supply amount by comparing the measured value of the load current of the driving motor M2 with the reference value of the load current of the driving motor. For example, the water supply amount may be controlled by controlling whether the pump motor M1 of the present invention is turned on/off and the time for which the pump motor M1 is in a turned on.

The water supply amount may be subdivided and optioned into “small, medium, large, no water,” for example. The “small, medium, large” means that the pump motor M1 is in the turn on state, and the wet cleaning is in progress. In this case, the long on-state time of the pump motor M1 is “large,” and the short on-state time of the pump motor M1 is “small.” Also, “no water” means that the pump motor M1 is in the turn off state.

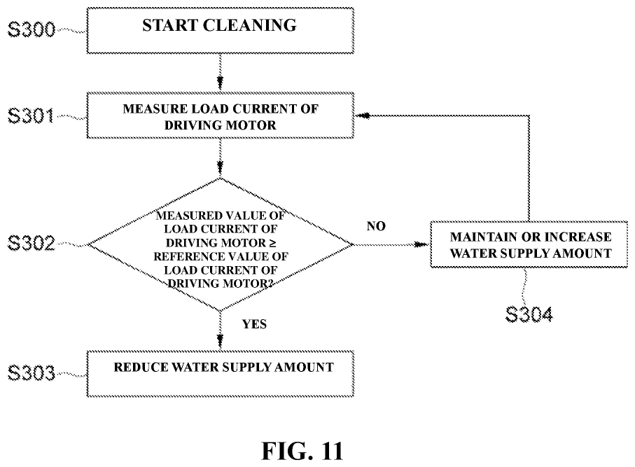

FIG. 11 is a flowchart illustrating a process of controlling a water supply amount of a robot cleaner according to an embodiment of the present invention.

First, the robot cleaner starts cleaning (S300). Here, dry cleaning may be performed without the pump motor M1 being driven according to control or a user selection, but hereinafter, it is assumed that wet cleaning is performed with the pump motor M1 being driven. The robot cleaner may travel as described above, and at the same time, water may be supplied to the cleaners 210, 220, and 230 to perform the wet cleaning.

In this case, the driving motor load current detection unit 172 measures the load current of the driving motor M2. The measured value of the load current is referred to as the “measured value of the load current of the pump motor.” In this case, the “reference value of the load current of the pump motor” is preset in the control unit 170. The reference value of the load current of the pump motor may be pre-stored in the control unit 170. In addition, a design change or a change by a user may be possible. In addition, the reference value of the load current of the driving motor may be set as a reference in a linear traveling or rotational traveling state of the robot cleaner.

The control unit 170 compares the measured value of the load current of the pump motor measured by the driving motor load current detection unit 172 with a preset reference value of the load current of the pump motor (S302).

The case in which the measured value of the load current of the driving motor is greater than the reference value of the load current of the driving motor is as follows.

When there is an obstacle in the course of the robot cleaner, the robot cleaner has a loop-like movement near the obstacle. Therefore, since the robot cleaner moves repeatedly in the corresponding area, the water supply amount per unit area of the surface to be cleaned increases compared to the case in which there is no obstacle.

As the amount of water present in the surface to be cleaned increases, due to the characteristics of the robot cleaner of the present invention which uses a frictional force of a wheelless cleaner and a surface to be cleaned as a moving force source, a load applied to the cleaners 210, 220, and 230 and the rotary members 110, 120, and 130 increases. This is because the so-called surface to be cleaned is slippery. Therefore, the measured value of the load current of the driving motor may be greater than the reference value of the load current of the driving motor.

Therefore, since the supply of water is already sufficient in the environment in which the load increases, there is a need to control the water supply amount to be reduced. This is because the increase in the load causes battery consumption and reduces the time available for cleaning.

Also, depending on the material of the surface to be cleaned, the measured value of the load current of the driving motor may be greater than the reference value of the load current of the driving motor.

For the surface to be cleaned, marble, general flooring, laminated flooring, etc., are usually used at home, and the surface to be cleaned is slippery in the order of marble—general flooring—laminated flooring. Therefore, when the robot cleaner cleans a surface to be cleaned made of marble, the measured value of the load current of the driving motor may be greater than the reference value of the load current of the driving motor. For the surface to be cleaned made of the slippery material, the water supply amount needs to be further reduced than the surface to be cleaned made of a relatively less slippery material. Therefore, there is a need to control the water supply amount to be reduced.

When the measured value of the load current of the driving motor is greater than or equal to the reference value of the load current of the driving motor, the control unit 170 reduces the water supply amount (S303). In the opposite case, the water supply amount may be maintained or increased according to the selection (S304). The measured value of the load current of the driving motor and the reference value of the load current of the driving motor are continuously compared through the feedback.

As described above, the reduction in the water supply amount is achieved by switching the pump motor M1 to the off state, and the total amount of the water supply amount to be reduced may be calculated through the off state time.

Conventionally, the water supply amount is controlled through a sensor that detects the amount of moisture in the surface to be cleaned, which has a problem of increasing manufacturing costs and causing a lot of A/S cases due to frequent breakdowns. However, in the present invention, the measured value of the load current of the driving motor may be compared with the reference value of the load current of the driving motor, and the water supply amount may be controlled by adjusting the on/off or on/off time of the pump motor M1, which has the advantage of reducing manufacturing costs. In addition, the structure is simplified compared to the existing sensor type, which has the advantage of lowering a failure rate of the robot cleaner.

In addition, according to the present invention, it is possible to avoid a driving obstacle section by determining the state of the surface to be cleaned in advance. As a result, it is possible to adjust the appropriate water supply, and secure efficient wet cleaning and cleaning time per unit time by reducing the battery consumption.

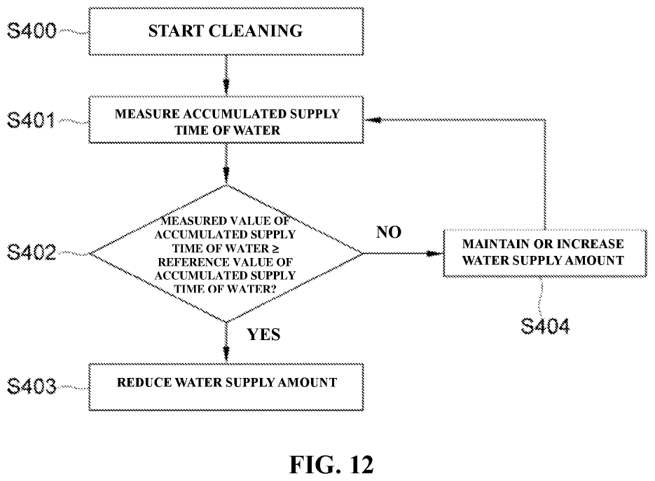

FIG. 12 is a flowchart illustrating a process of controlling a water supply amount of a robot cleaner according to another embodiment of the present invention.

The control of the water supply amount according to another embodiment of the present invention may be achieved by measuring the accumulated supply time of water. When cleaning starts (S400), the control unit 170 measures the accumulated supply time of water (S401). The measured time value is called the “measured value of the accumulated supply time of water.”

In this case, according to the design, the preset “reference value of the accumulated supply time of water” is compared with the measured value of the accumulated supply time of water (S402). When the measured value of the accumulated supply time of water is greater than or equal to the reference value of the accumulated supply time of water, the supply time of water further increases than the reference state determined to be normal, and as described above, since the loads on the rotary members 110, 120, and 130 increase, there is a need to control the water supply amount to decrease.

Therefore, in the case in which the measured value of the accumulated supply time of water is greater than or equal to the reference value of the accumulated supply time of water by comparing the reference value of the accumulated supply time of water with the measured value of the accumulated supply time of water, the control unit 170 reduces the water supply amount when the measured value of the load current of the driving motor is greater than or equal to the reference value of the load current of the driving motor (S403). In the opposite case, the water supply amount may be maintained or increased according to the selection (S304). The reference value of the accumulated supply time of water and the measured value of the accumulated supply time of water are continuously compared through the feedback.

As described above, according to the present invention, it is possible to detect the water shortage in the water tank or control the water supply amount through the process of measuring the load currents of the pump motor M1 and the driving motor M2 by the pump motor load current detection unit 171 and the driving motor load current detection unit 172 of the control unit 170 and comparing the measured value with the reference value. As a result, there is an advantage of reducing the manufacturing costs.

In addition, it is possible to avoid a traveling obstacle section by determining a condition of a surface to be cleaned in advance, and secure efficient wet cleaning and cleaning time per unit time by reducing battery consumption.

Meanwhile, the method of controlling a robot cleaner according to various exemplary embodiments of the present invention described above may be implemented by program codes and be provided in the respective servers or apparatuses in a state in which it is stored in various non-transitory computer-readable media.

The non-transitory computer-readable medium is not a medium that stores data therein for a while, such as a register, a cache, and a memory, but means a medium that semi-permanently stores data therein and is readable by an apparatus. In detail, the various applications or programs described above may be stored and provided in the non-transitory computer readable media such as a compact disk (CD), a digital versatile disk (DVD), a hard disk, a Blu-ray disk, a universal serial bus (USB), a memory card, and a read only memory (ROM).

In addition, although the exemplary embodiments of the present disclosure have been illustrated and described hereinabove, the present disclosure is not limited to the above-mentioned specific exemplary embodiments, but may be variously modified by those skilled in the art to which the present disclosure pertains without departing from the scope and spirit of the present disclosure as disclosed in the accompanying claims. These modifications should also be understood to fall within the scope of the present disclosure.

### INDUSTRIAL APPLICABILITY

The present invention is devised from the above needs, and an object of the present invention is to detect water shortage in a water tank or control water supply without a separate sensor to reduce manufacturing cost and reduce battery consumption to secure efficient wet cleaning and cleaning time per unit time by a process of measuring load currents of a pump motor and a driving motor by a pump motor load current detection unit and a driving motor load current detection unit of a control unit and comparing a measured value with a reference value.

1. A robot cleaner water shortage detection system, comprising:
a body;
a drive unit which is provided in the body to supply power for traveling of a robot cleaner;
a plurality of rotary members which rotate about a plurality of respective rotation axes by the power from the drive unit and to which cleaners for wet cleaning of a surface to be cleaned is be fixed respectively;
a water tank which is provided in the body to store water;
a pump motor which supplies water stored in the water tank to the rotary members; and
a control unit which measures a load current of the pump motor,
wherein a water shortage state in the water tank is detected based on a measured value of the load current of the pump motor.

2. The robot cleaner water shortage detection system of claim 1, wherein the water shortage state in the water tank is detected by comparing a preset reference value of the load current of the pump motor and the measured value of the load current of the pump motor.

3. The robot cleaner water shortage detection system of claim 2, wherein, when the measured value of the load current of the pump motor is less than or equal to the reference value of the load current of the pump motor, the water shortage state is notified to the user.

4. The robot cleaner water shortage detection system of claim 1, wherein the water shortage state in the water tank is detected based on a variation change of the measured value of the load current of the pump motor.

5. The robot cleaner water shortage detection system of claim 4, wherein, when a section where the variation change of the measured value of the load current of the pump motor is constant is repeated, the water shortage state is notified to a user.

6. The robot cleaner water shortage detection system of claim 1, wherein the robot cleaner travels by using a frictional force between the surface to be cleaned and the fixed cleaner, which is generated as the cleaner rotates, as a moving power source.

7. The robot cleaner water shortage detection system of claim 1, wherein the plurality of rotary members include a first rotary member, a second rotary member, and a third rotary member.

8. A water supply system for a robot cleaner, comprising:
a body;
a drive unit which is provided in the body to supply power for traveling of a robot cleaner;
a plurality of rotary members which rotate about a plurality of respective rotation axes by the power from the drive unit and to which cleaners for wet cleaning of a surface to be cleaned is be fixed respectively;
a driving motor which provides the power to the plurality of rotary members;
a water tank which is provided in the body to store water;
a pump motor which supplies water stored in the water tank to the rotary members; and
a control unit which measures a load current of the driving motor,
wherein a water supply amount of the water tank is controlled based on a measured value of the load current of the driving motor.

9. The water supply system of claim 8, wherein the water supply amount of the water tank is detected by comparing a preset reference value of the load current of the driving motor and the measured value of the load current of the driving motor.

10. The water supply system of claim 9, wherein, when the measured value of the load current of the driving motor is greater than or equal to the reference value of the load current of the driving motor, the water supply amount is controlled to be reduced.

11. The water supply system of claim 9, wherein the reference value of the load current of the driving motor is the reference value of the load current of the driving motor in a linear traveling or rotational traveling state of the robot cleaner.

12. The water supply system of claim 8, wherein the robot cleaner travels by using a frictional force between the surface to be cleaned and the fixed cleaner, which is generated as the cleaner rotates, as a moving power source.

13. The water supply system of claim 8, wherein the plurality of rotary members include a first rotary member, a second rotary member, and a third rotary member.
